(19) United States
(12) Patent Application Publication
(10) Pub. No.: US 2006/0278162 A1
(43) Pub. Date: Dec. 14, 2006

(54) Vacuum treatment apparatus and vapor deposition apparatus

(75) Inventors: Tadahiro Ohmi, Miyagi (JP); Yasuyuki Shirai, Miyagi (JP); Akihiro Morimoto, Miyagi (JP)

Correspondence Address: FOLEY AND LARDNER LLP;SUITE 500, 3000 K STREET NW, WASHINGTON, DC, 20007, US

(73) Assignee: Tadahiro Ohmi

(21) Appl. No.: 10/568,706

(22) PCT Filed: Aug. 19, 2004
(86) PCT No.: PCT/JP04/12239

§ 371 Date: Apr. 28, 2006

(30) Foreign Application Priority Data
Aug. 20, 2003 (JP) 2003-296439

(51) Int. Cl. C23C 16/00

(52) U.S. Cl. 118/715; 118/733; 118/50

(57) ABSTRACT

It has been found that an organic component is emitted from a member such as a crucible or a gasket constituting an apparatus for vacuum treatment and an element is contaminated with said organic component emitted, and, as a result, members of the apparatus for vacuum treatment are subjected to a treatment for reducing the emission of an organic component. For example, a crucible is made from a material having a reduced catalytic activity to a material for use in the vapor deposition in question and a gasket is used after a treatment for reducing the bleeding of an organic component or is made from a material containing a reduced amount of an organic component.

### TECHNICAL FIELD

This invention relates to a reduced-pressure processing apparatus, a vapor deposition apparatus, and so on and, in particular, relates to a reduced-pressure processing apparatus and a vapor deposition apparatus in which contamination such as organic matter is reduced. Hereinafter, an apparatus that carries out treatment at a pressure lower than the atmospheric pressure like the reduced-pressure processing apparatus or the vapor deposition apparatus will be collectively called a vacuum processing apparatus in this specification.

### BACKGROUND ART

When forming a film of a chemical substance with a low molecular weight on a substrate like in the case of an organic EL element, a vapor deposition method in a reduced-pressure atmosphere is widely used as a technique of easily forming a thin film with relatively good quality. A vapor deposition apparatus normally has a structure such that a pressure reducing pump is connected to a stainless or aluminum pressure-reduction container that has a structure reducible in pressure.

The pressure-reduction container is provided with a substrate holder for placing thereon a substrate serving as a film-forming object and a processing object introducing door that is opened and closed on placing the substrate. As the pressure reducing pump, is generally used a combination that consists of a molecular flow region pump (hereinafter referred to as a primary pump) such as a turbomolecular pump capable of achieving a high degree of vacuum and a dry pump or an oil rotary pump (hereinafter referred to as a secondary pump) connected to the discharge side of the primary pump for assisting the primary pump.

Airtightness between the processing object introducing door and the pressure-reduction container is generally ensured by interposing a rubber O-ring or the like between the door and the outer wall of the container. As the rubber O-ring, is generally used a fluoro-rubber O-ring such as Viton series manufactured by DuPont and, on selecting the rubber O-ring, attention is paid to mechanical properties such as size, resistance to chemicals, and plasma resistance.

A deposition source container is not particularly limited. However, in terms of heat resistance, use is made of a material such as quartz, graphite, glassy carbon, BN, or alumina.

As the vapor deposition apparatus of this type, descritption is made in Japanese Unexamined Patent Application Publication (JP-A) No. 2000-160328 (Patent Document 1), Japanese Unexamined Patent Application Publication (JP-A) No. H5-44021 (Patent Document 2), and Japanese Unexamined Patent Application Publication No. H8-321448 (Patent Document 3).

Patent Document 1 discloses a deposition source container (K-cell) that is used in a chemical substance deposition operation for heating and evaporating or sublimating a chemical substance in a vacuum and, in particular, realizes visualization of a deposition material in the K-cell. Patent Document 2 discloses a structure of a deposition source container (K-cell) in vacuum deposition and, in particular, enables uniformity of temperature of a deposited object in the K-cell. Further, Patent Document 3 discloses a reduced-pressure processing apparatus that reduces impurities remaining inside the reduced-pressure processing apparatus by reveres diffusion from the discharge side of a pump.

It has been found out that when the foregoing reduced-pressure processing apparatus including the vapor deposition apparatus is used, there arises a problem that a gas is emitted a lot from a constituent material of gaskets important for ensuring airtightness within the apparatus and components of this emitted gas contaminate a processing object in a pressure-reduction container or, in the case of the vapor deposition apparatus, are entrained in a deposited film. As a result, the properties of an element are degraded.

This will be explained concretely with reference to FIG. 1. FIG. 1 shows a reduced-pressure processing apparatus and a measurement system for measuring the amount of organic matter in the reduced-pressure processing apparatus. The reduced-pressure processing apparatus comprises a pressure-reduction container 1, a primary pump 2 connected to the pressure-reduction container 1, and a secondary pump 3 connected to the exhaust or evacuation side of the primary pump 2, and an atmospheric pressure ionization mass spectrometer (API-MS) 4 for measuring the amount of organic matter is attached to the pressure-reduction container 1. These members are connected through gaskets 5, 6, and 7 in structure to thereby ensure airtightness at connecting portions thereof.

Herein, a turbomolecular pump is used as the primary pump 2 and a dry pump generally used in the semiconductor manufacturing process is used as the secondary pump 3. According to a method described in Patent Document 3, an Ar gas is introduced to the exhaust side of the primary pump 2 and results in suppression of reverse diffusion of organic components and moisture from the exhaust side of the primary pump.

FIG. 2 shows measurement results obtained when fluoro-rubber O-rings (Viton) manufactured by DuPont, which are generally used in the semiconductor manufacturing process, are used as the gaskets 5, 6, and 7.

FIG. 2 shows the results of mass spectrometry of gas components in the pressure-reduction container 1 measured by the API-MS 4 and abscissa and ordinate represent a mass number and relative ion intensity (i.e. the number of detected molecules), respectively. As clear from FIG. 2, it is understood that peaks are mainly observed between molecular weights 40 and 240 and low-molecular organic matter is emitted.

When such emitted organic components are entrained in an organic EL layer or the like, it has been found out that problems such as reduction in luminance and reduction in element lifetime are caused.

Further, the present inventors have also recognized that there arises a problem wherein since an inner surface of a deposition source container has catalytic properties, has fine holes (voids), or is roughened, a deposition material is easily decomposed and decomposition products are entrained in a deposited film, thereby degrading the properties of an element.

On the other hand, although Patent Document 1 proposes visualization of the inside state of a deposition crucible by ensuring transparency of the crucible, no consideration is made about the quality of a deposition material in the deposition crucible. Further, no description is made about a structure of the vapor deposition apparatus in terms of contamination in a pressure-reduction container due to emission gas from gaskets and, therefore, high-quality deposition film formation cannot be carried out with this technique.

In Patent Document 2, the temperature of a deposition material in a crucible is uniformized by disposing a thermal insulation material outside the crucible, thereby ensuring the quality of a deposited film. However, no reference is made to the catalytic properties between the surface of the crucible and the deposition material and, therefore, the foregoing problem of decomposition of the deposition material due to the catalytic properties is not solved. Further, like in Patent Document 1, no reference is made to a structure of the vapor deposition apparatus and no description is given in terms of contamination in a pressure-reduction container due to emission gas from gaskets, and therefore, high-quality deposition film formation cannot be carried out even with this technique.

Further, although Patent Document 3 describes a structure of an exhaust pump of the reduced-pressure processing apparatus, no reference is made to a problem of emission gas from gaskets in the apparatus. Therefore, when the treatment is carried out in a state of high pressure-reduction degree like in the vapor deposition apparatus or the like, it is not possible solve the problem that the emission gas from the gaskets is entrained in the deposited film.

### DISCLOSURE OF THE INVENTION

This invention has been made in terms of the foregoing problems and is characterized by using a gasket with a small emission of organic matter in a reduced-pressure processing apparatus or a vapor deposition apparatus, wherein, as the gasket with the small emission of the organic matter, use is made of a metal or ceramic gasket at a portion where attach/detach frequency is low, while, use is made of a gasket containing organic matter at a portion where attach/detach frequency is high. It is characterized in that, as the gasket containing the organic matter, use is made of a gasket having been subjected to a process of contacting it with water at 80° C. or more, preferably boiling water (both preferably pure water, particularly ultrapure water) or a gasket containing a special fluoro-rubber or a perfluoroelastomer as a main component.

Further, a vapor deposition apparatus of this invention is characterized in that a deposition source container is made of a material with low catalytic properties or that a deposition source container is made of a material with a high thermal conductivity and an inner surface of the deposition source container is made of a material with low catalytic properties. Further, the deposition source container of this invention is characterized in that its inner surface is substantially smooth.

Further, the vapor deposition apparatus of this invention is characterized in that a deposition material is an organic EL material. Further, a vacuum processing apparatus or the vapor deposition apparatus of this invention is characterized in that a degree of vacuum at the time of treatment is 100 Torr or less.

Further, an organic EL element of this invention is characterized by comprising an organic film formed by the use of the vapor deposition apparatus as characterized above.

Further, an organic EL display device of this invention is characterized by comprising an organic film formed by the use of the vapor deposition apparatus as characterized above.

According to this invention, since, as described above, the material with the small emission of the organic matter is used as the gasket material, it is possible to suppress the problem that the organic matter emitted from the gaskets contaminates the inside of the pressure-reduction container or is entrained in the deposited film, thereby degrading the quality of the deposited film. By using this invention in vapor deposition of an organic EL layer, emitted organic components entrained into the organic EL layer are reduced and, therefore, it is possible to achieve improvement in luminance and luminescent lifetime of an organic EL element.

### BRIEF DESCRIPTION OF THE DRAWINGS

FIG. 1 is a schematic structural diagram showing a reduced-pressure processing apparatus normally used.

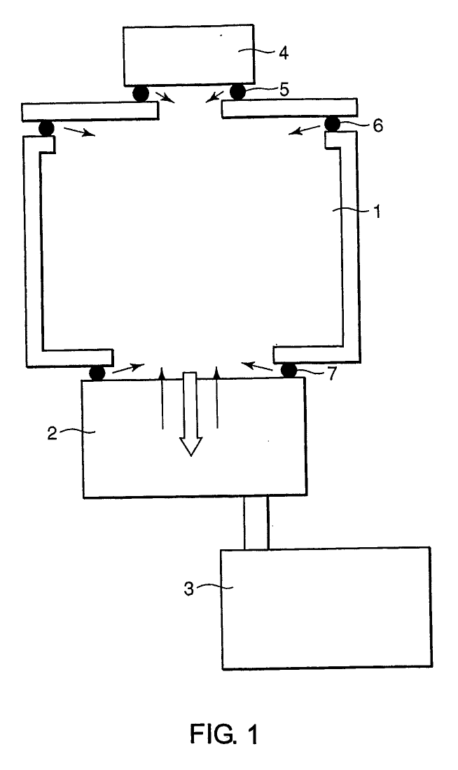

FIG. 2 is a diagram showing measurement results obtained when conventional gaskets are used.

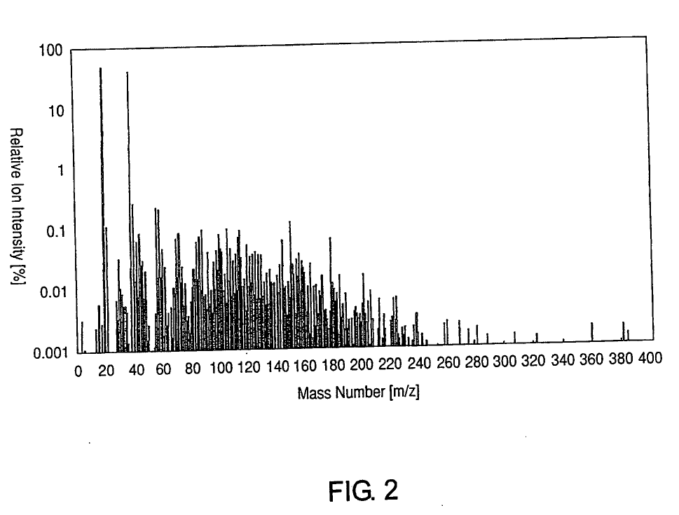

FIG. 3 is a graph showing measurement results about emission gas when gaskets according to this invention are used.

FIG. 4 is a graph showing measurement results about adsorption amounts of emitted organic components onto substrates when various kinds of gaskets are used.

FIG. 5 is a sectional view showing one example of a structure of a deposition source container for use in a vapor deposition apparatus of this invention.

FIG. 6 is a diagram showing a schematic structure of a vapor deposition apparatus according to Example 1 of this invention.

FIG. 7 is a diagram showing a schematic structure of a vapor deposition apparatus according to Example 2 of this invention.

### BEST MODE FOR CARRYING OUT THE INVENTION

A material with a small emission of organic matter defined in this invention represents at least one of a metal and a ceramic in which the content of organic matter is extremely low or an organic material which has a small emission amount of organic matter. More specifically, the material with the small emission of the organic matter has a state where, when a gasket having a surface area of 1 cm² is made of such a material, the relative ion intensity measured by an API-MS in atmospheric-pressure Ar at a flow rate of 1.2 l/min after heating to 100° C. does not exceed 0.1% at a molecular weight of 100 or more, and more preferably does not exceed 0.01%.

As such an organic material, there is preferably cited an organic material having been subjected to a process of contacting it with water at 80° C. or more, preferably boiling water (both preferably pure water, particularly ultrapure water), a perfluoroelastomer, or the like. However, the organic material is not limited thereto as long as it is a material with a small emission of organic matter. It has been confirmed that, by contacting the organic material with water at 80° C. or more, preferably boiling water (both preferably pure water, particularly ultrapure water) so as to clean it, unnecessary organic matter contained inside the gasket is eluted so that the emission amount of organic matter can be reduced. On the other hand, use may be made of a material, such as a perfluoroelastomer, with a low content of additives or decomposition products.

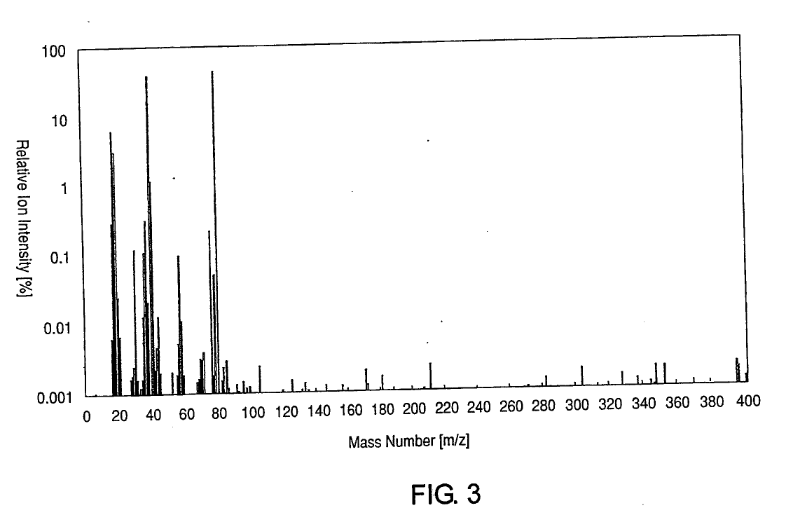

FIG. 3 shows results of measuring emission gas from the perfluoroelastomer and clarifies the fact that emitted organic components having a molecular weight of 100 or more are extremely small.

In this invention, a material of a gasket for use in a vacuum processing apparatus such as a reduced-pressure processing apparatus or a vapor deposition apparatus is selected depending on whether attach/detach frequency of the gasket is high or low. Herein, a portion with low attach/detach frequency represents a portion where attach/detach is not carried out for a week or more, preferably a month or more, and more preferably a year or more in operation of the apparatus, while, a portion with high attach/detach frequency represents a portion other than it. For example, in the vacuum processing apparatus, a processing object introducing door or the like that is opened and closed when removing a processing object in less than a week from its introduction into the apparatus is a portion with high attach/detach frequency, while, a gasket or the like interposed between a process chamber, which is detached and subjected to maintenance once in a year or once in several years, and a pump is a portion with low attach/detach frequency. At the portion with the low attach/detach frequency, it is preferable to use a metal gasket or a ceramic gasket with a less emission of organic matter. The metal gasket or the ceramic gasket is preferably replaced at every time when attach/detach operation is carried out and, therefore, it is not economically preferable to use the metal or ceramic gasket at the portion with the high attach/detach frequency because of enormous cost for maintenance and management of the apparatus, while, it is preferable to use a low-priced organic gasket with a small emission of organic matter.

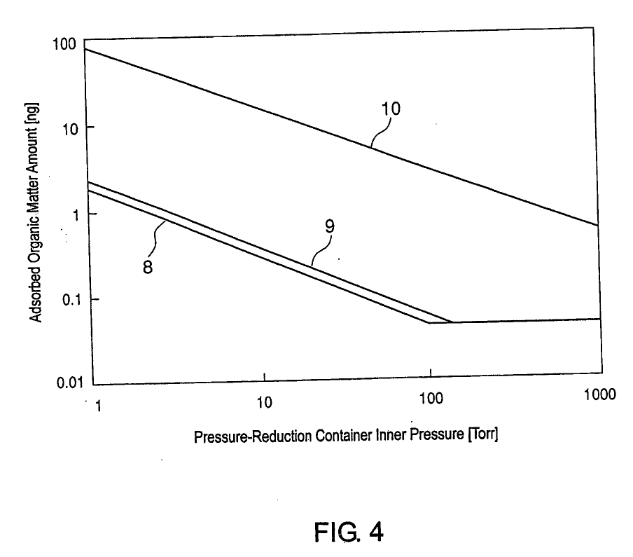

Referring now to FIG. 4, description will be made about results of measuring adsorption amounts of emitted organic components, emitted from organic gaskets, onto substrates. FIG. 4 shows the results of cases in each of which a 6-inch glass substrate is placed in a reduced-pressure processing apparatus having organic gaskets and the total adsorption amount of organic components, emitted from the organic gaskets, on the 6-inch glass substrate is measured by a gas chromatography-mass spectrometry. A curve 8 shows the case where perfluoroelastomer gaskets are used. A curve 9 shows the case where generally used fluoro-rubber gaskets are used after cleaning them with pure water at 80° C. Further, a curve 10 shows the case where generally used fluoro-rubber gaskets are used after cleaning them with pure water at room temperature. As clear from comparison among them, the case of the perfluoroelastomer gaskets (curve 8) and the case of the gaskets subjected to boil cleaning (curve 9) each show organic matter adsorption amounts sufficiently lower as compared with the case of the generally used fluoro-rubber gaskets (curve 10). Particularly, since the emission amount of organic matter increases with a reduction of a vapor pressure within a range not higher than a pressure of 100 Torr, it is understood that this invention is suitable for a reduced-pressure processing apparatus or a vapor deposition apparatus that carries out treatment at the pressure of 100 Torr or less.

Further, in the vacuum processing apparatus, particularly the vapor deposition apparatus, according to this invention, the quality of a film to be deposited can be further improved not only by selecting the gasket material depending on the attach/detach frequency, but also by selecting a material of a container to be filled with a deposition material.

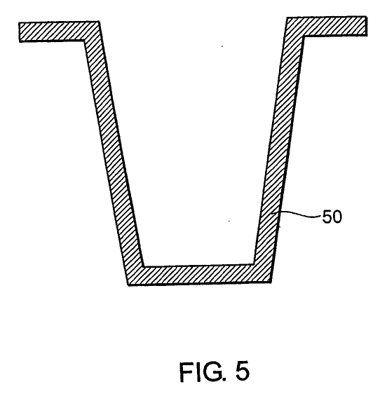

Referring to FIG. 5, there is shown a deposition source container for use in the vapor deposition apparatus according to this invention and, in this figure, there is shown a section of a deposition source container 50 for use in the vapor deposition apparatus of this invention. A material forming the illustrated deposition source container 50 is a material having low catalytic properties with respect to a deposition material to be filled and, specifically, an oxide or a nitride of an element selected from Si, Cr, Al, La, Y, Ta, and Ti is chemically stable and suitable. For example, Al₂O₃, Cr₂O₃, AlN, Y₂O₃, La₂O₃, MgO, or the like is preferable. Particularly, it is sufficient that the catalytic properties be low only at a portion to be in contact with the deposition material and, therefore, the foregoing material with the low catalytic properties may be formed on the inner surface of a deposition source container made of a high thermal conductivity material, such as tungsten, having a thermal conductivity of 1 W/mK or more. The formation may be carried out according to a plasma spraying method or by sputtering, for example, Al according to a sputtering method and then oxidizing or nitriding it. When the deposition source container is made of the high thermal conductivity material, the heat from a heater provided outside the container can be efficiently conducted to the deposition material and, therefore, it is suitable in terms of maintaining homogeneity of a deposited film and enhancing the energy efficiency. The structure of the deposition source container for use in the vapor deposition apparatus of this invention is not limited to the foregoing bottomed hollow cylindrical shape and may have any shape as long as the deposition material can be loaded and heated. As such a shape, a boat shape or a dish shape can be cited as an example.

Further, the inner surface of the deposition source container 50 for use in the vapor deposition apparatus of this invention is preferably a substantially smooth surface. The substantially smooth surface defined in this invention is surfaces that appears smooth with respect to a deposition material, wherein the center line average roughness is preferably 100 nm or less, more preferably 10 nm or less, and further preferably nm or less. Since this reduces an effective surface area where molecules of the deposition material contact the deposition source container, it is possible to suppress decomposition of the deposition material at the interface between the deposition source container and the deposition material.

According to the vapor deposition apparatus of this invention, since the material with the low catalytic properties is used for the deposition source container or the inner surface thereof, it is possible to suppress decomposition of a deposition material, particularly an organic material such as an organic EL material and thus it is possible to reduce the amount of impurities contained in an organic EL element or an organic film of a display device. Therefore, it is possible to improve the luminance and the luminescent lifetime of the element. Further, according to the vapor deposition apparatus of this invention, since the inner surface of the deposition source container is a substantially flat surface, it is possible to reduce the surface area of contact between the deposition material and the deposition source container. Thus, the decomposition amount of the deposition material can be reduced and therefore it is possible to reduce the amount of impurities contained in the organic EL element or the organic film of the display device. Accordingly, it is possible to improve the luminance and the luminescent lifetime of the element.

### EXAMPLE 1

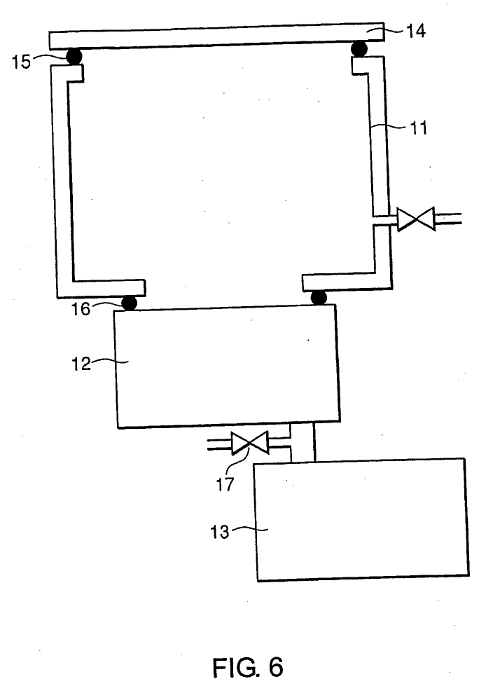

Referring to FIG. 6, description will be made about a reduced-pressure processing apparatus in Example 1 of this invention. FIG. 6 is a sectional view showing one example of the reduced-pressure processing apparatus of this Example 1, wherein it comprises a pressure-reduction container 11, an exhaust primary pump 12 connected to the pressure-reduction container 11, an exhaust secondary pump 13 connected to the discharge side of the primary pump, a gas introduction mechanism 17 existing between the primary pump 12 and the secondary pump 13, a processing object introducing door 14 connected to the pressure-reduction chamber 11 so as to be opened and closed when taking in or out a processing object, and a first gasket 15 and a second gasket 16 interposed between the processing object introducing door 14 and the pressure-reduction container 11 and between the pressure-reduction container 11 and the primary pump 12 for ensuring airtightness at connecting portions thereof. Herein, open/close frequency, i.e. attach/detach frequency, of the processing object introducing door 14 is extremely higher as compared with attach/detach frequency of the primary pump 12.

A turbomolecular pump was used as the primary pump 12, while a screw dry pump was used as the secondary pump 13. In this case, 100 sccm Ar was led through the gas introduction mechanism 17 to thereby suppress back or reverse diffusion of impurities from the screw dry pump 13. A Cu gasket was used as the secondary gasket 16, while a perfluoroelastomer gasket was used as the first gasket 15.

Since the first gasket 15 at the processing object introducing door portion 14 with high attach/detach frequency was made of a perfluoroelastomer with a small emission of organic matter, it was possible to suppress the amount of impurities in the pressure-reduction container 11 and thus it was possible to suppress adsorption of impurities to a processing substrate (not shown).

### EXAMPLE 2

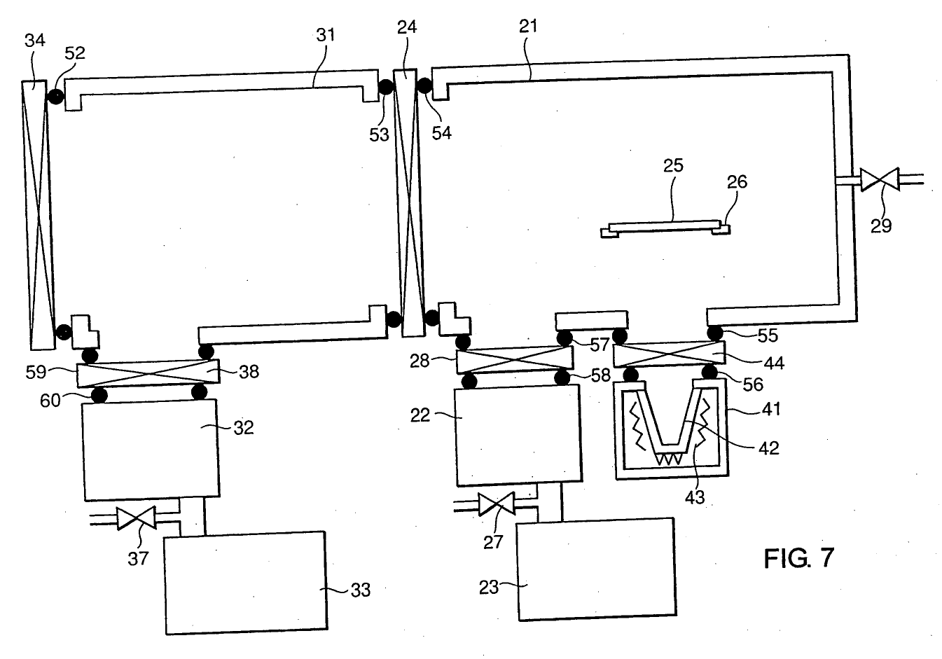

Referring to FIG. 7, description will be made about a vapor deposition apparatus in Example 2 of this invention. FIG. 7 is a sectional view showing one example of the vapor deposition apparatus of this Example 2. The illustrated apparatus comprises a process chamber 21 for carrying out vapor deposition, a substrate introducing chamber 31 connected to the process chamber 21 through a gate valve 24, serving as a partition between the process chamber 21 and the substrate introducing chamber 31 and ensuring airtightness of the process chamber 21, for taking in and out a substrate 25, a substrate introducing door 34 connected to the substrate introducing chamber 31, a substrate holder 26 for holding the substrate 25 in the process chamber 21, primary pumps 22 and 32 connected to the process chamber 21 and the substrate introducing chamber 31 through pump gate valves 28 and 38, respectively, secondary pumps 23 and 33 connected to the discharge sides of the primary pumps 22 and 32, respectively, pump purge gas introduction mechanisms 27 and 37 located between the primary pumps 22 and 32 and the secondary pumps 23 and 33 for suppressing back diffusion of impurities from the secondary pumps 23 and 33, a process chamber gas introduction mechanism 29 for introducing a gas into the process chamber 21, a deposition source chamber 41 having a deposition source container 42 therein, the deposition source container 42 loaded with a deposition source (not shown), a heater 43 for heating the deposition source container 42, a shutter mechanism 44 existing between the deposition source chamber 41 and the process chamber 21 for stopping vapor deposition at an unnecessary time, and gaskets 52, 53, 54, 55, 56, 57, 58, 59, and 60 existing at connecting portions of the respective members for ensuring airtightness to the exterior. Among the gaskets, in the vapor deposition apparatus in this Example, the gaskets 52 and 56 which were present between the substrate introducing door 34 and the substrate introducing chamber 31 and between the deposition source chamber 41 and the shutter mechanism 44 were made of a perfluoroelastomer, while the other gaskets 53, 54, 55, 57, 58, 59, and 60 were made of Cu.

With this configuration, the gaskets containing the organic matter can be minimized as required and, further, even the gaskets containing the organic matter are made of the material whose organic matter emission is very small. Therefore, impurities emitted from the gaskets can be suppressed from being entrained into an organic thin film formed on the substrate 25. Further, since the deposition source container 42 was made of Al₂O₃ and its inner surface was formed substantially flat by polishing, any catalytic properties scarcely appeared and it was possible to suppress thermal decomposition of the deposition material inside the decomposition source container 42.

As a result of forming an organic EL layer by the use of this vapor deposition apparatus and measuring the properties of an organic EL element, the luminance at the same current was improved by 30% and the luminance half-decay lifetime became twice, i.e. 10000 hours, as compared with the case of using conventional general fluoro-rubber gaskets and general deposition source container. Since the organic matter emission from the gaskets was suppressed and the decomposition of the deposition material in the deposition source container was suppressed, the impurities were suppressed from being entrained into the organic EL layer so that it was possible to improve the luminance and lifetime.

### Effect of the Invention

As described above, according to the reduced-pressure processing apparatus or the vapor deposition apparatus of this invention, since the material with the small emission of the organic matter is used as the gasket material, it is possible to suppress the problem that the organic matter emitted from the gaskets contaminates the inside of the reduced-pressure processing apparatus or is entrained in the deposited film, thereby degrading the quality of the processing object. By using this invention in the vapor deposition of the organic EL layer, the emitted organic components entrained into the organic EL layer are reduced and, therefore, it is possible to achieve the improvement in luminance and luminescent lifetime of the organic EL element.

Further, according to the vapor deposition apparatus of this invention, since the material with the low catalytic properties is used for the deposition source container or the inner surface thereof, it is possible to suppress the decomposition of the deposition material, particularly the organic material such as the organic EL material and thus it is possible to reduce the amount of the impurities contained in the organic EL element or the organic film of the display device. Therefore, it is possible to improve the luminance and the luminescent lifetime of the element. Further, according to the vapor deposition apparatus of this invention, since the inner surface of the deposition source container is the substantially flat surface, it is possible to reduce the surface area of contact between the deposition material and the deposition source container. Thus, the decomposition amount of the deposition material can be reduced and therefore it is possible to reduce the amount of the impurities contained in the organic EL element or the organic film of the display device. Accordingly, it is possible to improve the luminance and the luminescent lifetime of the element.

### INDUSTRIAL APPLICABILITY

The vapor deposition apparatus according to this invention has the structure capable of reducing generation of organic matter inside the apparatus and therefore is suitable for manufacturing a display device, which is required to prevent contamination due to organic matter, particularly an organic EL element.

1. A vacuum processing apparatus comprising a pressure-reduction container, exhaust means joined to said pressure-reduction container, and a processing object introducing door connected to said pressure-reduction container through a gasket, said vacuum processing apparatus characterized in that one or more gaskets including said gasket of said processing object introducing door are made of a material with a small emission of organic matter.

2. A vacuum processing apparatus according to claim 1, characterized in that the constituent material of said gasket contains organic matter.

3. A vacuum processing apparatus according to claim 2, characterized in that the constituent material of said gasket has been subjected to a process of contacting it with water at 80° C. or more.

4. A vacuum processing apparatus according to claim 2, characterized in that a main component of said organic matter is a perfluoroelastomer.

5. A vacuum processing apparatus comprising a pressure-reduction container, exhaust means connected to said pressure-reduction container, a processing object introducing door connected to said pressure-reduction container, and a plurality of gaskets for ensuring airtightness of said pressure-reduction container, said vacuum processing apparatus characterized in that a constituent material of the gasket, in said plurality of gaskets, for ensuring airtightness of a portion with low attach/detach frequency is at least one of a metal, a ceramic, and organic matter.

6. A vacuum processing apparatus according to claim 5, characterized in that a constituent material of the gasket for ensuring airtightness of a portion with high attach/detach frequency contains organic matter.

7. A vacuum processing apparatus according to claim 6, characterized in that at least one or more of the gaskets containing the organic matter have been subjected to a process of contacting them with water at 80° C. or more.

8. A vacuum processing apparatus according to claim 6, characterized in that a main component of said organic matter is a perfluoroelastomer.

9. A vacuum processing apparatus according to claim 1, characterized in that said exhaust means comprises a pump and causes a small amount of an inert gas to flow upstream of said pump or at a pump purge portion.

10. A vacuum processing apparatus according to claim 1, characterized in that said exhaust means comprises a primary pump, a secondary pump connected to an exhaust side of said primary pump, and a gas introducing portion for introducing an inert gas between said primary pump and said secondary pump.

11. A vacuum processing apparatus according to claim 1, characterized in that a degree of vacuum at the time of treatment is 100 Torr or less.

12. A vacuum processing apparatus according to claim 1, characterized in that said vacuum processing apparatus is a reduced-pressure processing apparatus.

13. A vacuum processing apparatus according to claim 1, characterized in that said vacuum processing apparatus is a vapor deposition apparatus.

14. A vapor deposition apparatus comprising a pressure-reduction container, exhaust means connected to said pressure-reduction container, a substrate introducing door connected to said pressure-reduction container, a plurality of gaskets for ensuring airtightness of said pressure-reduction container, and a deposition source container, said vapor deposition apparatus characterized in that a constituent material of the gasket, in said plurality of gaskets, for ensuring airtightness of a portion with low attach/detach frequency is at least one of a metal and a ceramic.

15. A vapor deposition apparatus according to claim 14, characterized in that a constituent material of the gasket for ensuring airtightness of a portion with high attach/detach frequency contains organic matter.

16. A vapor deposition apparatus according to claim 15, characterized in that said gasket containing the organic matter has been subjected to a process of contacting it with water at 80° C. or more.

17. A vapor deposition apparatus according to claim 15, characterized in that a main component of said organic matter is a perfluoroelastomer.

18. A vapor deposition apparatus according to claim 15, characterized in that said deposition source container is made of a material with low catalytic properties.

19. A vapor deposition apparatus according to claim 18, characterized in that an inner surface of said deposition source container contains at least one of an oxide or a nitride of an element selected from Si, Cr, Al, La, Y, Ta, Ti, and B, or C.

20. A vapor deposition apparatus according to claim 15, characterized in that said deposition source container is made of a high thermal conductivity material.

21. A vapor deposition apparatus according to claim 20, characterized in that said high thermal conductivity material forming said deposition source container contains at least one of a nitride of Al, B, or Si, C or a metal material.

22. A vapor deposition apparatus according to claim 21, characterized in that an inner surface of said deposition source container contains at least one of an oxide or a nitride of an element selected from Si, Cr, Al, La, Y, Ta, Ti, and B, or C.

23. A vapor deposition apparatus according to claim 19, characterized in that the inner surface of said deposition source container is substantially smooth.

24. A vapor deposition apparatus according to claim 14, characterized in that a deposition material put into said deposition source container is an organic EL element material.

25. A vapor deposition apparatus according to claim 14, characterized in that said exhaust means comprises a pump and causes a small amount of an inert gas to flow upstream of said pump or at a pump purge portion.

26. A vapor deposition apparatus according to claim 14, characterized in that said exhaust means comprises a primary pump, a secondary pump connected to a discharge side of said primary pump, and a gas introducing portion for introducing an inert gas between said primary pump and said secondary pump.

27. A vapor deposition apparatus according to claim 14, characterized in that a degree of vacuum at the time of treatment is 100 Torr or less.

28. An organic EL element characterized by comprising an organic layer formed by the use of the vapor deposition apparatus according to claim 14.

29. An organic EL display device characterized by comprising an organic layer formed by the use of the vapor deposition apparatus according to claim 14.

30. A vacuum processing apparatus comprising a plurality of airtight sealing members, said vacuum processing apparatus characterized in that at least one of said plurality of airtight sealing members has been applied with an organic matter emission prevention process.

31. A vacuum processing apparatus according to claim 30, characterized in that the airtight sealing member having been applied with said organic matter emission prevention process is subjected to higher attach/detach frequency as compared with the other airtight sealing member.

32. A vacuum processing apparatus comprising a plurality of airtight sealing members employed at portions that are detachably used, said vacuum processing apparatus characterized in that, in said plurality of airtight sealing members, the airtight sealing member at the portion with high attach/detach frequency and the airtight sealing member at the portion with low attach/detach frequency are made of mutually different materials and said airtight sealing member at said portion with the high attach/detach frequency is made of the material containing a perfluoroelastomer as a main component.
